(19) United States
(12) Patent Application Publication
(10) Pub. No.: US 2026/0191122 A1
(43) Pub. Date: Jul. 2, 2026

(54) DIE-BONDING METHOD THAT ALLOWS DIE-BONDING DEVICE TO ADAPT TO ANGLE OF SUBSTRATE

(71) Applicant: SAULTECH TECHNOLOGY CO., LTD., Zhubei City (TW)

(72) Inventor: YEN HAO LU, Zhubei City (TW)

(21) Appl. No.: 19/058,095

(22) Filed: Feb. 20, 2025

(30) Foreign Application Priority Data
Dec. 27, 2024 (TW) 113151369

(51) Int. Cl. H01L 23/00

(52) U.S. Cl. CPC H10W 99/00; H10W 72/011; H10W 72/071; H10W 80/161; H10W 80/163

(57) ABSTRACT

A die-bonding method that allows a die-bonding device to adapt to an angle of a substrate includes: the die-bonding device is located in a chamber of a transfer device, sides of a top of the die-bonding device are against a bottom of a transfer device, a bottom of the die-bonding device passes through an opening at bottom of the transfer device and absorbs a die by negative pressure, and the transfer device provides positive pressure on the top of the die-bonding device; move the transfer device above a substrate, and align the die with a die placement area of the substrate; move the transfer device downward, the die contact the die placement area, and the substrate provides a reaction force to the die-bonding device; and the die-bonding device floats in the chamber to adapt to an angle of the substrate to fit the die to die placement area.

### BACKGROUND OF THE INVENTION

### 1. Field of the Invention

The present invention relates generally to a die-bonding method, and more particularly, to die-bonding method that allows die-bonding device to adapt to angle of substrate.

### 2. the Prior Arts

Integrated circuits are manufactured in large quantities through multiple processes on semiconductor wafers, and the wafers are further divided into a plurality of dies. In other words, a die is a small piece of integrated circuit made of semiconductor materials and not packaged. The divided dies are neatly attached to a carrier, and then a carrier frame is responsible for transporting the carrier. The die-bonding device then sequentially transfers the dies to a substrate for subsequent processing.

However, the conventional die-bonding method utilizes a connecting rod to move the die-bonding device. The quality of the die-bonding is easily affected by the track accuracy (rigidity) of the connecting rod. When the die-bonding device applies pressure, a lateral force is generated on the die, which causes the angle and position of the die placement area where the die is fixed to the substrate to easily deviate.

Furthermore, some substrates are tilted relative to the die. Since the transfer device limits the angle of the die-bonding device, the die-bonding device applies uneven force to the die and the die placement area.

### SUMMARY OF THE INVENTION

A primary objective of the present invention is to provide a die-bonding method that allows die-bonding device to adapt to angle of substrate, and the angle and position of the die fixed in the die placement area are accurate.

Another objective of the present invention is to provide a die-bonding method that allows die-bonding device to adapt to angle of substrate, and the force applied to the die and the die placement area is relatively uniform.

To achieve the foregoing objectives, the present invention provides a die-bonding method that allows die-bonding device to adapt to angle of substrate, comprising the following steps: (a) a first image capture unit captures the image of at least one first positioning mark in a die placement area of a substrate; (b) a die-bonding device is arranged in a chamber of a transfer device, and sides of the top of the die-bonding device is abutted against the bottom of the transfer device, the chamber has a height greater than thickness of the top of the die-bonding device and a width greater than width of the top of the die-bonding device, the bottom of the die-bonding device passes through an opening at the bottom of the transfer device and absorbs a die by a negative pressure, the opening has an diameter greater than width of the bottom of the transfer device, and the transfer device provides a positive pressure acting on the top of the die-bonding device; (c) a second image capture unit captures an image of at least one second positioning mark of the die; (d) according to the image of at least one first positioning mark of the die placement area and the image of at least one second positioning mark of the die, a control unit moves the transfer device to above the substrate and the die aligns with the die placement area; (e) the transfer device is moved downward until the die contacts the die placement area, the die forms an angle greater than or equal to 0 degrees and less than 90 degrees with the substrate, and the substrate provides a reaction force to act on the die-bonding device through the die; and (f) in a positive pressure environment, the die-bonding device is acted by the reaction force to float in the chamber and the opening to adapt to the angle of the substrate until the die is fully affixed to the die placement area.

In some embodiments, step (b) further includes: a through hole of the transfer device is provided to communicate the chamber to an outside space.

In some embodiments, the through hole is opened at the top of the transfer device, or the through hole is opened at the top and side of the transfer device.

In some embodiments, step (b) further includes: an exhaust pipe of the transfer device passes through the top of the transfer device and the top and bottom of the die-bonding device, and the exhaust pipe provides the negative pressure.

In some embodiments, step (b) further includes: a through hole on the top of the transfer device is provided to communicate the chamber to an outside space, the exhaust pipe passes through the through hole, and the through hole has a diameter larger than the outer diameter of the exhaust pipe.

In some embodiments, step (b) further includes: a plurality of air inlet pipes of the transfer device pass through the top of the transfer device, communicate with the chamber, are aligned with the top of the die-bonding device, and provide the positive pressure.

In some embodiments, step (b) further includes: an air supply device provides air to the chamber through the air inlet pipes to generate the positive pressure.

In some embodiments, step (b) further includes: the air inlet pipes are arranged in a surrounding manner on the top of the transfer device.

In some embodiments, step (b) further includes: a film is fixed to the transfer device and contacts the top surface of the top of the die-bonding device.

In some embodiments, step (b) further includes: an exhaust pipe of the transfer device passes through the top of the transfer device, the film, and the top and bottom of the die-bonding device, and the exhaust pipe provides the negative pressure.

The effectiveness of the present invention lies in that the present invention can provide positive pressure to the die-bonding device through the transfer device, and at the same time provide sufficient space for the die-bonding device through the chamber and the opening. In a positive pressure environment, the die-bonding device can float in the chamber and the opening to rotate or lie flat to adapt to the angle of the substrate through the reaction force provided by the substrate, so that the angle and position of the die fixed in the die placement area are accurate and will not cause deviations.

Furthermore, even if the substrate is tilted with respect to the die (i.e., the angle is greater than 0 degrees and less than 90 degrees), the die-bonding device applies force to the die and the die placement area more evenly because the transfer device does not limit the angle of the die-bonding device.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a flow chart of the method of the present invention.

FIG. 2 is a schematic view of step S10 of the first embodiment of the method of the present invention.

FIG. 3 is a schematic view of step S20 and step S30 of the first embodiment of the method of the present invention.

FIG. 4 is a cross-sectional view taken along line IV-IV of FIG. 3

FIG. 5 is a schematic view showing the connection relationship among the transfer device, a vacuum device, and the air supply device of the present invention.

FIG. 6 is a schematic view showing the connection relationship between the first image capturing unit, the second image capturing unit, and the control unit of the present invention.

FIG. 7 and FIG. 8 are schematic views of step S40 of the first embodiment of the method of the present invention.

FIG. 9 and FIG. 10 are schematic views of step S50 and step S60 of the first embodiment of the method of the present invention.

FIG. 11 is a schematic view of step S10 of the second embodiment of the method of the present invention.

FIG. 12 is a schematic view of step S20 and step S30 of the second embodiment of the method of the present invention.

FIG. 13 and FIG. 14 are schematic views of step S40 of the second embodiment of the method of the present invention.

FIG. 15 and FIG. 16 are schematic views of step S50 and step S60 of the second embodiment of the method of the present invention.

FIG. 17 is a schematic view of step S20 and step S30 of the third embodiment of the method of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

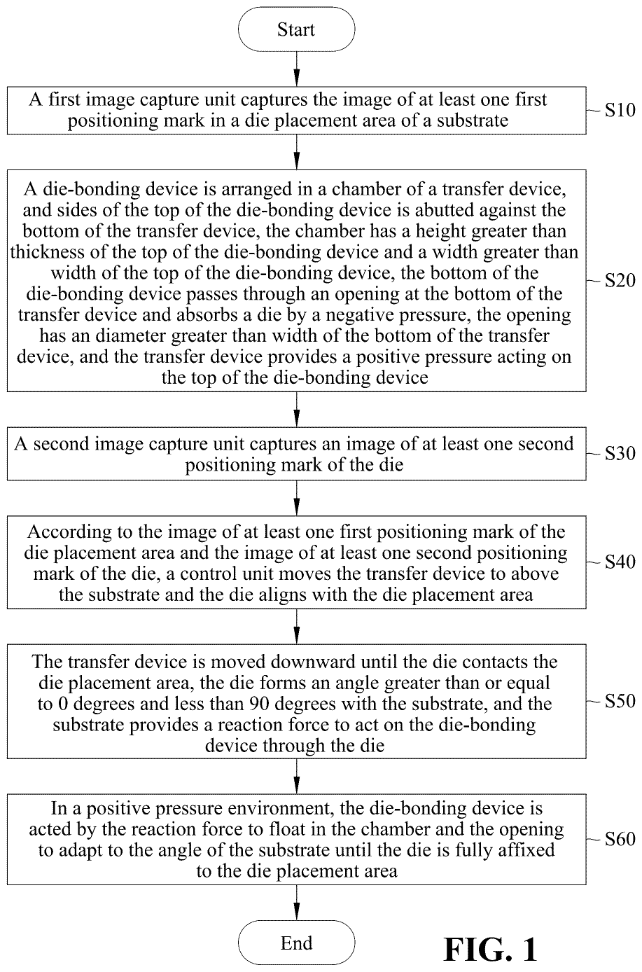

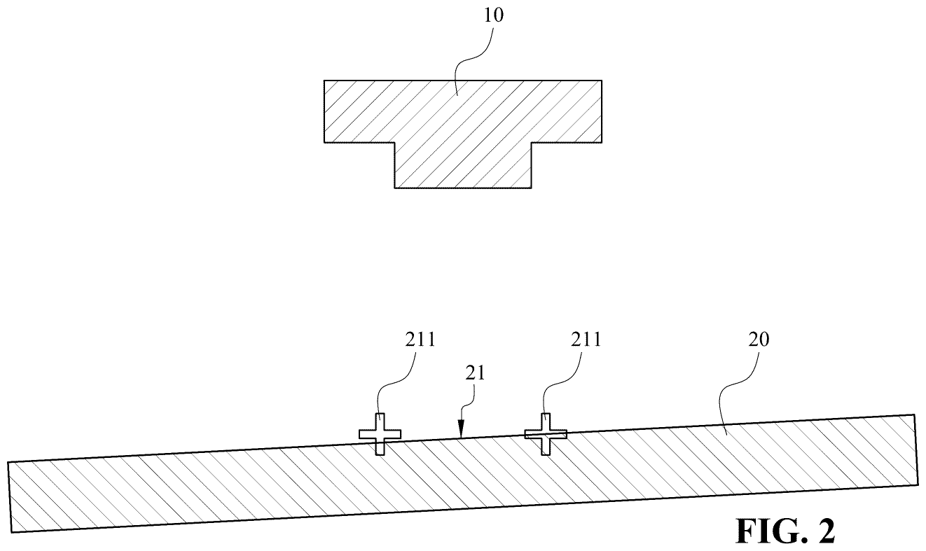

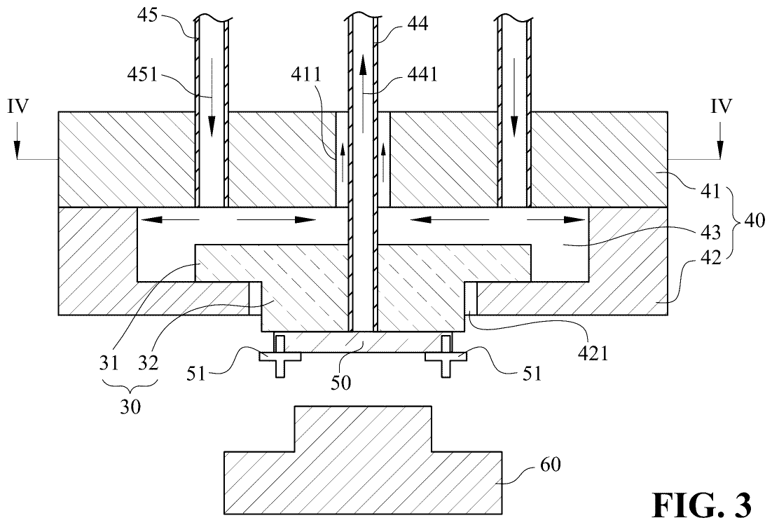

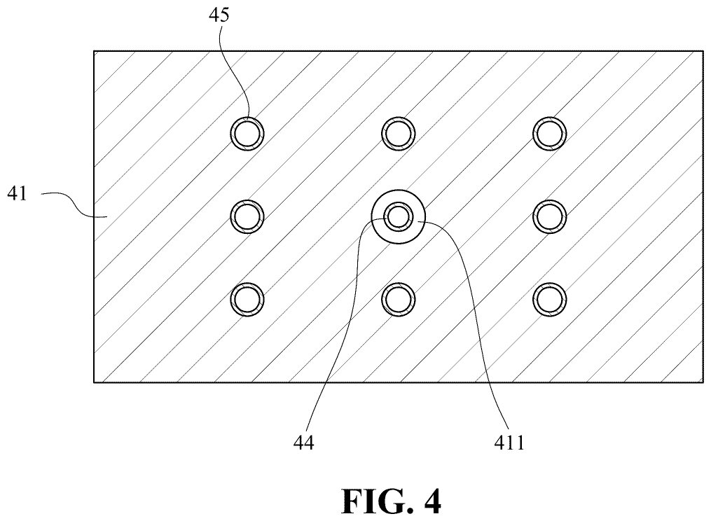

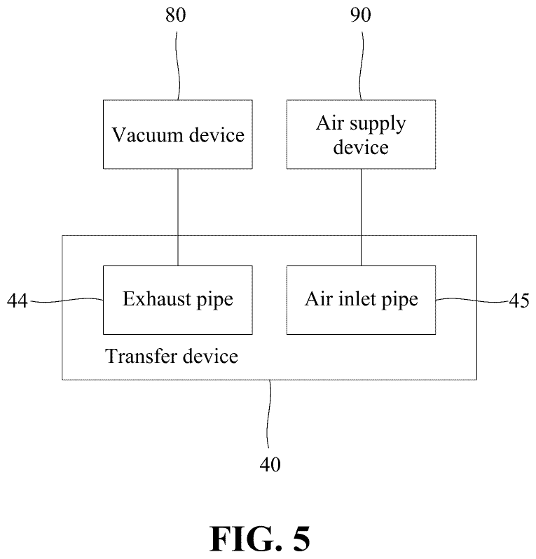

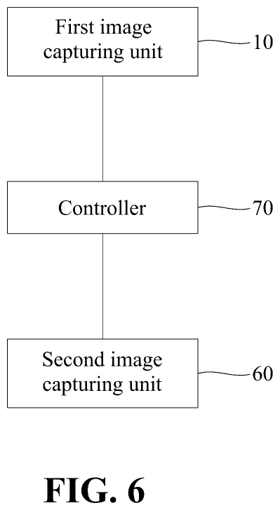

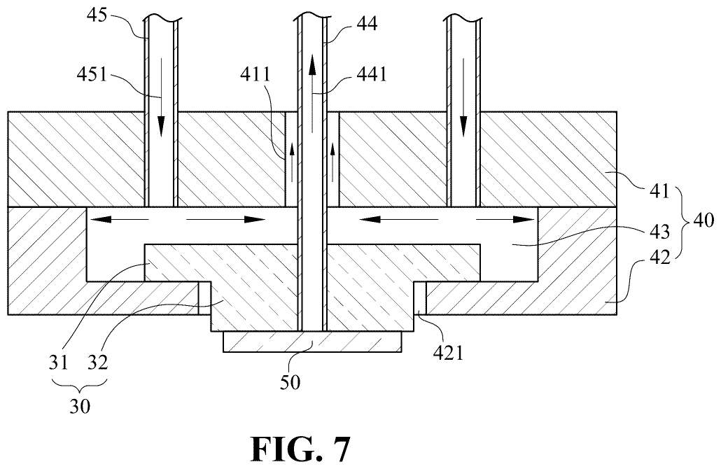

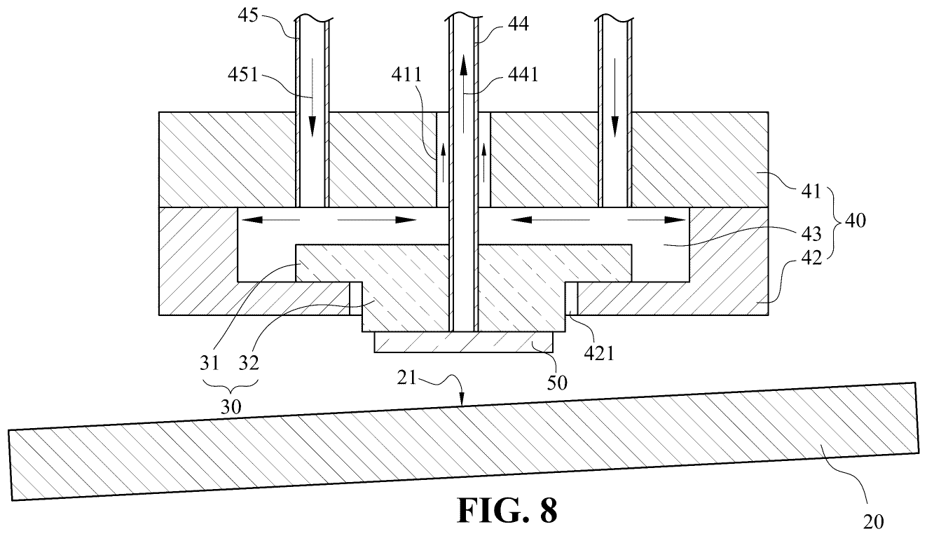

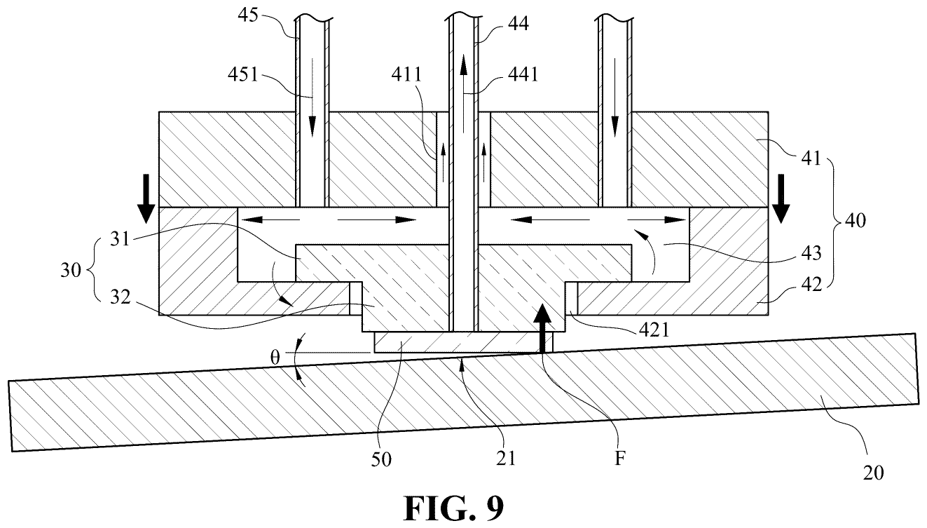

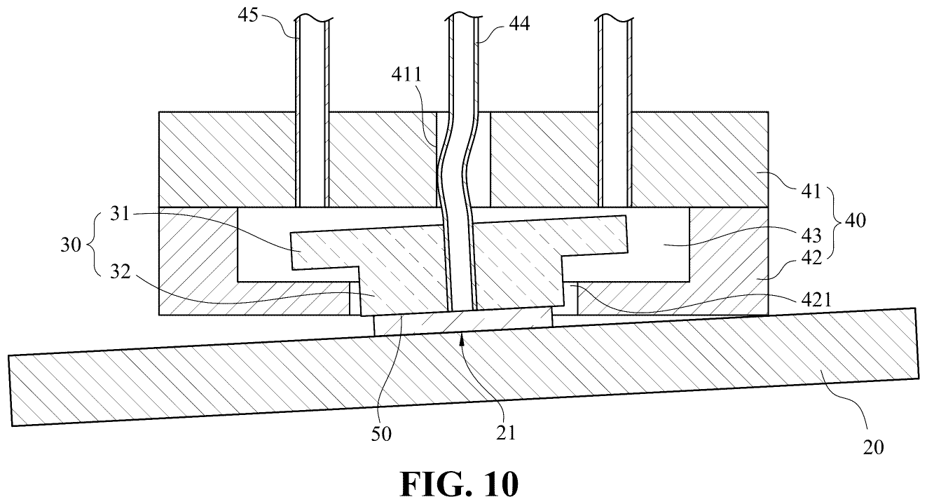

FIG. 1 is a flow chart of the method of the present invention. FIG. 2 is a schematic view of step S10 of the first embodiment of the method of the present invention. FIG. 3 is a schematic view of step S20 and step S30 of the first embodiment of the method of the present invention. FIG. 4 is a cross-sectional view taken along line IV-IV of FIG. 3. FIG. 5 is a schematic view showing the connection relationship among the transfer device, a vacuum device, and the air supply device of the present invention. FIG. 6 is a schematic view showing the connection relationship between the first image capturing unit, the second image capturing unit, and the control unit of the present invention. FIG. 7 and FIG. 8 are schematic views of step S40 of the first embodiment of the method of the present invention. FIG. 9 and FIG. 10 are schematic views of step S50 and step S60 of the first embodiment of the method of the present invention. The present invention provides a die-bonding method that allows die-bonding device to adapt to angle of substrate, comprising the following steps:
In step S10, as shown in FIG. 1 and FIG. 2, a first image capturing unit 10 captures images of two first positioning marks 211 of a die placement area 21 of a substrate 20.

In step S20, as shown in FIGS. 1, 3, 4, and 5, a die-bonding device 30 is disposed in a chamber 43 of a transfer device 40, the sides of the top 31 of the die-bonding device 30 abut against the bottom 42 of the transfer device 40, the height of the chamber 43 is greater than the thickness of the top 31 of the die-bonding device 30, the width of the chamber 43 is greater than the width of the top 31 of the die-bonding device 30, the bottom 32 of the die-bonding device 30 passes through an opening 421 of the bottom 42 of the transfer device 40 and adsorbs a die 50 by a negative pressure 441, the diameter of the opening 421 is greater than the width of the bottom 42 of the transfer device 40, and the transfer device 40 provides a positive pressure 451 acting on the top surface of the top 31 of the die-bonding device 30.

In step S30, as shown in FIG. 1 and FIG. 3, a second image capturing unit 60 captures images of two second positioning marks 51 of the die 50.

In step S40, as shown in FIGS. 1, 6, 7, and 8, a control unit 70 moves the transfer device 40 to above the substrate 20 according to the images of the first positioning marks 211 of the die placement area 21 and the images of the second positioning marks 51 of the die 50, and aligns the die 50 with a die placement area 21.

In step S50, as shown in FIG. 1 and FIG. 9, the transfer device 40 is moved downward, and one side of the die 50 contacts one side of the die placement area 21. There is an angle θ between the die 50 and the substrate 20, and the angle θ is greater than 0 degrees and less than 90 degrees. The substrate 20 provides a reaction force F to act on the die-bonding device 30 through the die 50.

In step S60, as shown in FIGS. 1, 9, and 10, in the positive pressure 451 environment, the die-bonding device 30 floats and rotates in the chamber 43 and the opening 421 by the reaction force F to adapt to the angle of the substrate 20 until the die 50 is completely attached to the die placement area 21.

In some embodiments, in step S40, the angle θ is equal to 0 degrees; in step S50, the bottom surface of the die 50 contacts the surface of the die placement area 21; in step S60, in the positive pressure 451 environment, the die-bonding device 30 floats and lies flat in the chamber 43 and the opening 421 by the reaction force F to adapt to the angle of the substrate 20.

Thereby, the present invention can provide positive pressure 451 to act on the die-bonding device 30 through the transfer device 40, and at the same time provide sufficient space for the die-bonding device 30 through the chamber 43 and the opening 421. In the positive pressure 451 environment, the die-bonding device 30 can float and rotate or lie flat in the chamber 43 and the opening 421 through the reaction force F provided by the substrate 20 to adapt to the angle of the substrate 20, so that the angle and position of the die 50 fixed in the die placement area 21 are accurate and no deviation will occur.

Furthermore, even if the substrate 20 is tilted with respect to the die 50 (i.e., the angle θ is greater than 0 degrees and less than 90 degrees), the die-bonding device 30 applies a more uniform force to the die 50 and the die placement area 21 because the transfer device 40 does not limit the angle of the die-bonding device 30.

In addition, during the movement of the transfer device 40, the present invention can provide the positive pressure 451 through the transfer device 40 to act on the top 31 of the die-bonding device 30 to prevent the die-bonding device 30 from shaking. The present invention can also absorb the die 50 through the negative pressure 441 to prevent the die 50 from detaching from the die-bonding device 30.

In the first embodiment, step S20 further includes: as shown in FIG. 3 and FIG. 4, a through hole 411 of the top 41 of the transfer device 40 is communicated with the chamber 43 and an outside space. More specifically, the chamber 43 is not airtight. Specifically, the positive pressure 451 of the transfer device 40 is formed by the air that continuously enters the chamber 43. If the chamber 43 is airtight, the chamber 43 will explode due to excessive pressure. If the chamber 43 is not airtight, the air in the chamber 43 can flow into the outside space through the through hole 411, so that the chamber 43 can maintain a certain pressure and will not explode due to excessive pressure.

In the first embodiment, step S20 further includes: as shown in FIG. 3 and FIG. 4, an exhaust pipe 44 of the transfer device 40 penetrates the top 41 of the transfer device 40 as well as the top 31 and bottom 32 of the die-bonding device 30, and the exhaust pipe 44 provides a negative pressure 441. Specifically, as shown in FIG. 5, a vacuum device 80 evacuates the exhaust pipe 44 to generate a vacuum and provide the negative pressure 44. As shown in FIG. 10, the exhaust pipe 44 is a deformable hose. In some embodiments, the exhaust pipe 44 may also be a non-deformable hard pipe.

Preferably, step S20 further includes: as shown in FIG. 3 and FIG. 4, the exhaust pipe 44 passes through the through hole 411, and the diameter of the through hole 411 is larger than the outer diameter of the exhaust pipe 44. Thereby, the present invention can reduce the cost of drilling additional holes in the transfer device 40 for the exhaust pipe 44 to pass through. Furthermore, the exhaust pipe 44 will not affect the air in the chamber 43 from flowing into the outside space through the through hole 411.

In the first embodiment, step S20 further includes: as shown in FIG. 3 and FIG. 4, a plurality of air inlet pipes 45 of the transfer device 40 penetrate the top 41 of the transfer device 40, communicate with the chamber 43, align with the top of the die-bonding device 30, and provide the positive pressure 451. Specifically, as shown in FIG. 5, an air supply device 90 provides air to the chamber 43 via the air inlet pipes 45 to generate a positive pressure 451. The air inlet pipes 45 are deformable hoses. In some embodiments, the air inlet pipes 45 may also be non-deformable hard pipes. Thereby, the positive pressure 451 provided by the air inlet pipes 45 can evenly act on the top 31 of the die-bonding device 30, so that the force applied to the die 50 and the die placement area 21 is more even.

Preferably, step S20 further comprises: as shown in FIG. 3 and FIG. 4, the air inlet pipes 45 are disposed around the top 41 of the transfer device 40. Thereby, the positive pressure 451 provided by the air inlet pipes 45 can act on the top 31 of the die-bonding device 30 more evenly, so that the force applied to the die 50 and the die placement area 21 is more even.

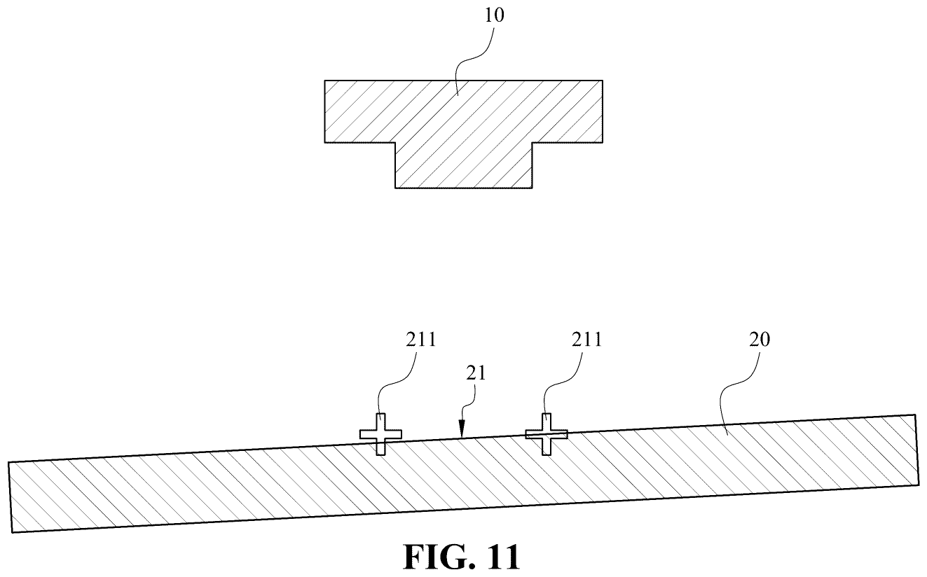

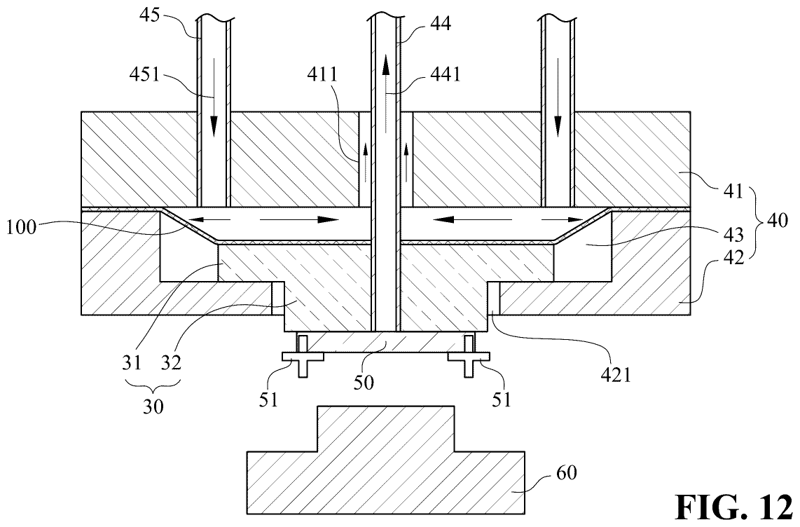

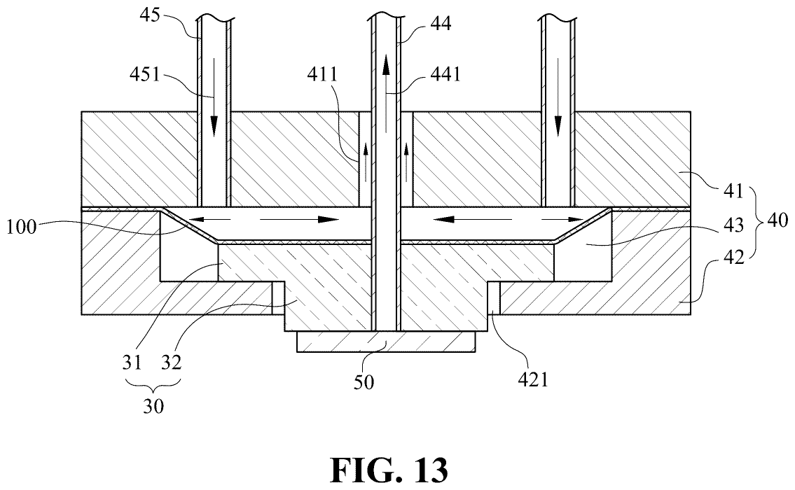

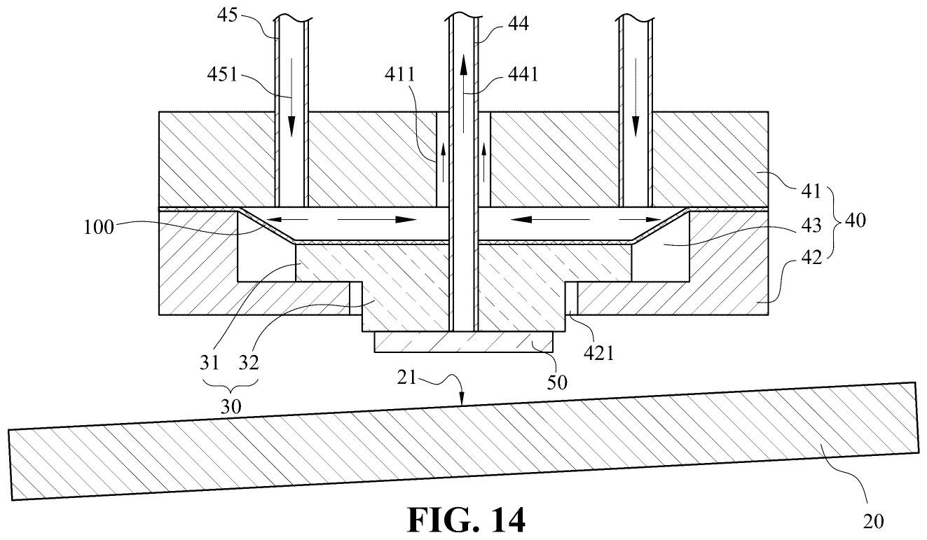

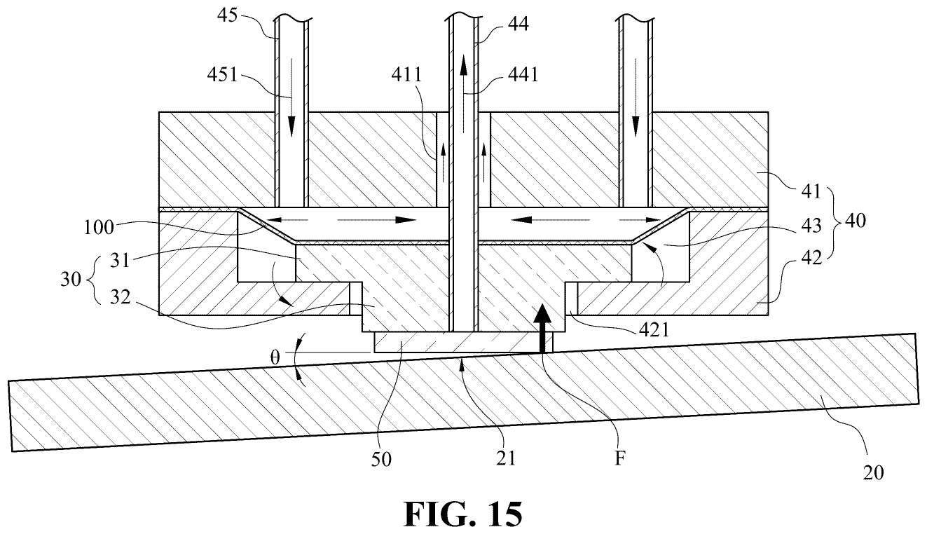

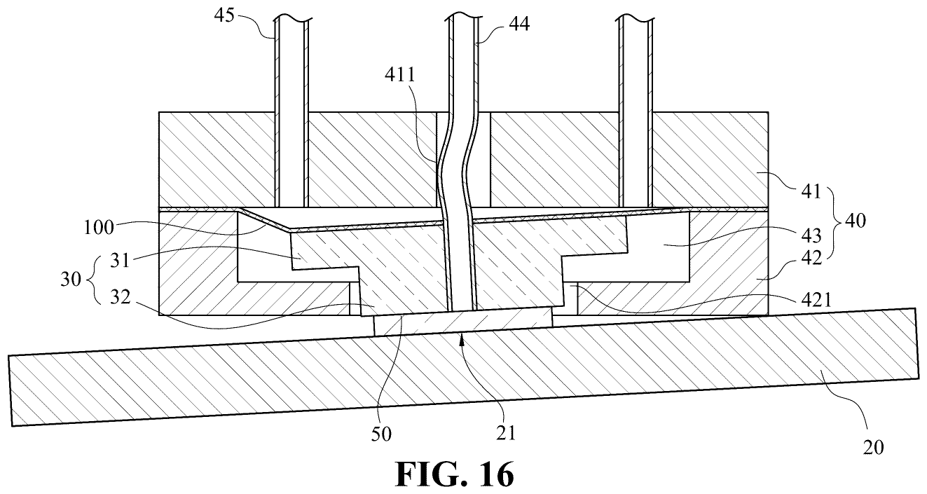

FIG. 11 is a schematic view of step S10 of the second embodiment of the method of the present invention. FIG. 12 is a schematic view of step S20 and step S30 of the second embodiment of the method of the present invention. FIG. 13 and FIG. 14 are schematic views of step S40 of the second embodiment of the method of the present invention. FIG. 15 and FIG. 16 are schematic views of step S50 and step S60 of the second embodiment of the method of the present invention. As shown in FIGS. 11 to 16, the difference between the second embodiment and the first embodiment is that: first, step S20 further includes: a film 100 is fixed to the transfer device 40 and contacts the top surface of the top 31 of the die-bonding device 30, and the exhaust pipe 44 passes through the film 100. Compared to the first embodiment, because the film 100 contacts the top surface of the top 31 of the die-bonding device 30, the film 100 allows the positive pressure 451 to act more evenly on the top 31 of the die-bonding device 30, making the force applied to the die 50 and the die placement area 21 more even.

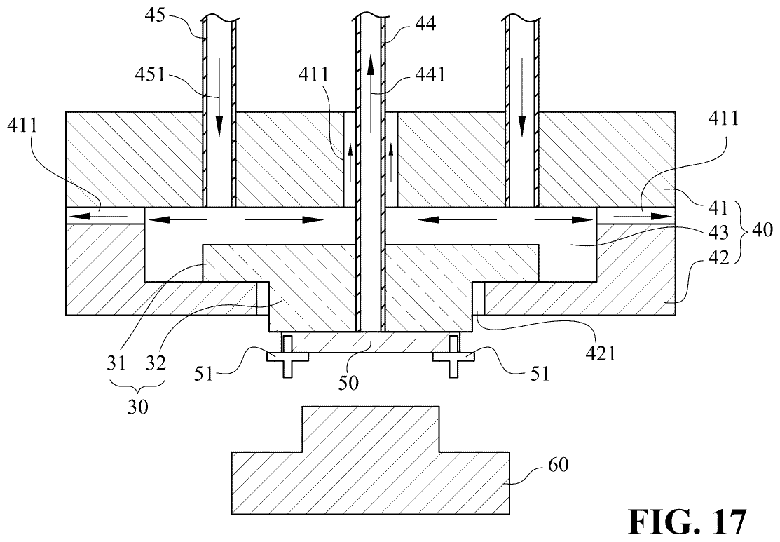

FIG. 17 is a schematic view of step S20 and step S30 of the third embodiment of the method of the present invention. As shown in FIG. 17, the difference between the third embodiment and the first embodiment is that a plurality of through holes 411 are respectively provided on the top 41 and the side of the transfer device 40. The through holes 411 on the side of the transfer device 40 can also make the chamber 43 present a non-sealed state and achieve the same effect.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A die-bonding method that allows die-bonding device to adapt to angle of substrate, comprising the following steps:
(a) a first image capture unit captures the image of at least one first positioning mark in a die placement area of a substrate;
(b) a die-bonding device is arranged in a chamber of a transfer device, and sides of the top of the die-bonding device is abutted against the bottom of the transfer device, the chamber has a height greater than thickness of the top of the die-bonding device and a width greater than width of the top of the die-bonding device, the bottom of the die-bonding device passes through an opening at the bottom of the transfer device and absorbs a die by a negative pressure, the opening has an diameter greater than width of the bottom of the transfer device, and the transfer device provides a positive pressure acting on the top of the die-bonding device;
(c) a second image capture unit captures an image of at least one second positioning mark of the die;
(d) according to the image of at least one first positioning mark of the die placement area and the image of at least one second positioning mark of the die, a control unit moves the transfer device to above the substrate and the die aligns with the die placement area;
(e) the transfer device is moved downward until the die contacts the die placement area, the die forms an angle greater than or equal to 0 degrees and less than 90 degrees with the substrate, and the substrate provides a reaction force to act on the die-bonding device through the die; and
(f) in a positive pressure environment, the die-bonding device is acted by the reaction force to float in the chamber and the opening to adapt to the angle of the substrate until the die is fully affixed to the die placement area.

2. The die-bonding method that allows die-bonding device to adapt to angle of substrate according to claim 1, wherein step (b) further includes: a through hole of the transfer device is provided to communicate the chamber to an outside space.

3. The die-bonding method that allows die-bonding device to adapt to angle of substrate according to claim 2, wherein the through hole is opened at the top of the transfer device, or the through hole is opened at the top and side of the transfer device.

4. The die-bonding method that allows die-bonding device to adapt to angle of substrate according to claim 1, wherein step (b) further includes: an exhaust pipe of the transfer device passes through the top of the transfer device and the top and bottom of the die-bonding device, and the exhaust pipe provides the negative pressure.

5. The die-bonding method that allows die-bonding device to adapt to angle of substrate according to claim 4, wherein step (b) further includes: a through hole on the top of the transfer device is provided to communicate the chamber to an outside space, the exhaust pipe passes through the through hole, and the through hole has a diameter larger than the outer diameter of the exhaust pipe.

6. The die-bonding method that allows die-bonding device to adapt to angle of substrate according to claim 1, wherein step (b) further includes: a plurality of air inlet pipes of the transfer device pass through the top of the transfer device, communicate with the chamber, are aligned with the top of the die-bonding device, and provide the positive pressure.

7. The die-bonding method that allows die-bonding device to adapt to angle of substrate according to claim 6, wherein step (b) further includes: an air supply device provides air to the chamber through the air inlet pipes to generate the positive pressure.

8. The die-bonding method that allows die-bonding device to adapt to angle of substrate according to claim 6, wherein step (b) further includes: the air inlet pipes are arranged in a surrounding manner on the top of the transfer device.

9. The die-bonding method that allows die-bonding device to adapt to angle of substrate according to claim 1, wherein step (b) further includes: a film is fixed to the transfer device and contacts the top surface of the top of the die-bonding device.

10. The die-bonding method that allows die-bonding device to adapt to angle of substrate according to claim 9, wherein step (b) further includes: an exhaust pipe of the transfer device passes through the top of the transfer device, the film, and the top and bottom of the die-bonding device, and the exhaust pipe provides the negative pressure.
